(19) United States
(12) Patent Application Publication
(10) Pub. No.: US 2012/0141658 A1
(43) Pub. Date: Jun. 7, 2012

(54) COATING METHOD FOR SPACERS OF LIQUID CRYSTAL SUBSTRATE AND MANUFACTURING METHOD FOR LIQUID CRYSTAL SUBSTRATE

(75) Inventors: CHENG-CHUAN CHAN, Shenzhen (CN); Chengming He, Shenzhen (CN)

(73) Assignee: Shenzhen China Star Optoelectronics Technology Co., LTD., Shenzhen City (CN)

(21) Appl. No.: 13/220,653

(22) Filed: Aug. 29, 2011

(30) Foreign Application Priority Data
Dec. 1, 2010 (CN) 201010575233.6

(51) Int. Cl. B05D 5/12; C23C 16/52

(52) U.S. Cl. 427/8; 427/58

(57) ABSTRACT

A coating method for spacers of a liquid crystal substrate and a manufacturing method for the liquid crystal substrate are disclosed. The coating method for spacers of the liquid crystal substrate has steps of: providing a glass substrate which has a conductive cladding on a surface thereof and further has a display region and a drop-allowing region; cleaning a surface of the conductive cladding; and distributing droplets of spacers onto the surface of the conductive cladding on the drop-allowing region of the glass substrate. Advantages of the present invention are to directly apply the droplets of spacers onto the surface of the conductive cladding before coating an alignment film, so as to ensure the cleanness of the coated surface. Thus, it is advantageous to spread out the droplets of spacers and inhibit the sliding thereof.

### FIELD OF THE INVENTION

The present invention relates to a manufacture field of liquid crystal displays, and more particularly to a coating method for spacers of liquid crystal substrate and a manufacturing method for liquid crystal substrate.

### BACKGROUND OF THE INVENTION

In a traditional technology, the manufacture of a liquid crystal display (LCD) needs to carry out processes of: coating alignment films, coating spacers, applying sealants, assembling upper and lower substrates, cutting out cracked pieces, milling to form chamfers, filling liquid crystal and sealing substrates in turn. The process of coating spacers is executed after the process of coating alignment films (polyimide, PI). Because the alignment film has been coated on the substrate, the surface of the alignment film can not be further modified to clean the surface of the substrate by means of atmospheric pressure plasma and Excimer-UV. Once the surface of the substrate is not cleaned enough, it is not easy for the droplet of spacers to spread out from a spherical status into a flat status, wherein the spherical droplet of spacers is relatively easy to slide. If the droplet of spacers slides out of a drop-allowing region, it will cause problems of substrate rework and discard.

Referring now to FIG. 1, a schematic view of a structure after forming spacers on a surface of an alignment file by a traditional coating method is illustrated, and comprises a liquid crystal substrate 10, a conductive cladding 11, an alignment film 12 and spacers 13. The liquid crystal substrate 10 further comprises display regions 101 and drop-allowing regions 102, wherein the display regions 101 are three types of color resists (i.e. red R, green G, and blue B) which are used to carry out a display function of LCD, while the drop-allowing regions 102 is black matrixes which have no display function. The surface of the conductive cladding 11 is coated with the alignment film 12, and then the surface of the alignment film 12 is dropped with the spacers 13, so as to obtain the foregoing structure. During coating the alignment film 12, the surface thereof after coating is easy to be contaminated by dirt. Because the material of the alignment film 12 is soft, it is not suitable to be further cleaned by means of atmospheric pressure plasma and Excimer-UV. However, if the surface of the alignment film 12 is not cleaned enough, it is not easy for the droplet of spacers 13 to spread out from a spherical droplet into a flat status, but it basically keeps the similar spherical droplet of spacers 13 just after dropping, as shown in FIG. 1. As a result, the spherical spacers 13 is easy to slide on the surface of the alignment film 12. For more details, to prevent from affecting the normal display effect of the display regions 101, the dropping process needs to allow the spacers 13 to be dropped on the drop-allowing regions 102. However, the width of the drop-allowing regions 102 is generally only about 31 μm. Once the spacers 13 slide on the surface of the alignment film 12, it is easy to cause that the spacers 13 slide into the display regions 101, resulting in affecting the display effect of a final product.

### SUMMARY OF THE INVENTION

To solve the foregoing technical problems, a primary object of the present invention is to provide a coating method for spacers of a liquid crystal substrate and a manufacturing method for a liquid crystal substrate, which can allow droplets of spacers to be fully spread out on a dropping position, so as to inhibit the sliding thereof.

To solve the foregoing problems, the present invention provides a coating method for spacers of a liquid crystal substrate which comprises: providing a glass substrate, wherein a surface of the glass substrate has a conductive cladding and the glass substrate has a display region and a drop-allowing region; cleaning a surface of the conductive cladding; and distributing droplets of spacers onto the surface of the conductive cladding on the drop-allowing region of the glass substrate.

As a possible technical solution of the present invention, after distributing the droplets of spacers onto the surface of the conductive cladding on the drop-allowing region of the glass substrate, further comprising the following step of: keeping stationary the glass substrate distributed with the droplets of spacers, so that the droplets of spacers are spread out to be flat on the surface of the conductive cladding.

As a possible technical solution of the present invention, after the droplets of spacers are spread out to be flat, further comprising the following step of: detecting if the surface of the conductive cladding on the display region is distributed with the droplets of spacers; and if there are the droplets of spacers, clearing the droplets of spacers on the surface of the conductive cladding.

As a possible technical solution of the present invention, after clearing the droplets of spacers on the surface of the conductive cladding, further comprising the following step of: re-executing the steps of cleaning the surface of the conductive cladding and distributing the droplets of spacers.

As a possible technical solution of the present invention, the step of clearing the droplets of spacers on the surface of the conductive cladding comprises: using a brush cleaning process to clear the droplets of spacers on the surface of the conductive cladding.

The present invention further provides a manufacturing method for a liquid crystal substrate which comprises: providing a glass substrate, wherein a surface of the glass substrate has a conductive cladding and the glass substrate has a display region and a drop-allowing region; cleaning a surface of the conductive cladding; distributing droplets of spacers onto the surface of the conductive cladding on the drop-allowing region of the glass substrate; and coating an alignment film on the surface of the conductive cladding distributed with the droplets of spacers, wherein the alignment film is filled into gaps between the spacers.

As a possible technical solution of the present invention, after distributing the droplets of spacers onto the surface of the conductive cladding on the drop-allowing region of the glass substrate and before coating the alignment film on the surface of the conductive cladding distributed with the droplets of spacers, further comprising the following step of: keeping stationary the glass substrate distributed with the droplets of spacers, so that the droplets of spacers are spread out to be flat on the surface of the conductive cladding.

As a possible technical solution of the present invention, after the step of coating the alignment film, further comprising the following step of: curing the glass substrate to solidify the alignment film and further fix positions of the droplets of spacers.

As a possible technical solution of the present invention, after the droplets of spacers are spread out to be flat, further comprising the following step of: detecting if the surface of the conductive cladding on the display region is distributed with the droplets of spacers; and if there are the droplets of spacers, clearing the droplets of spacers on the surface of the conductive cladding.

As a possible technical solution of the present invention, after clearing the droplets of spacers on the surface of the conductive cladding, further comprising the following step of: re-executing the steps of cleaning the surface of the conductive cladding and distributing the droplets of spacers.

Advantages of the present invention are to directly apply the droplets of spacers onto the surface of the conductive cladding, so as to ensure the cleanness of the coated surface. Thus, it is advantageous to spread out the droplets of spacers and inhibit the sliding thereof.

Furthermore, the physical and chemical properties of the conductive cladding are stable. Thus, in a case that deviation of applying positions of the droplets of spacers is found, it is easy to remove the droplets of spacers and rework. Only if a suitable cleaning process is selected, it can ensure that the conductive cladding will not be scratched.

Moreover, after coating the alignment film, the step of curing is executed, so that the droplets of spacers can be further fixed on the drop-allowing region of the glass substrate to prevent from shifting.

### DESCRIPTION OF THE DRAWINGS

FIG. 1 is a schematic view of a structure after forming spacers on a surface of an alignment file by a traditional coating method;

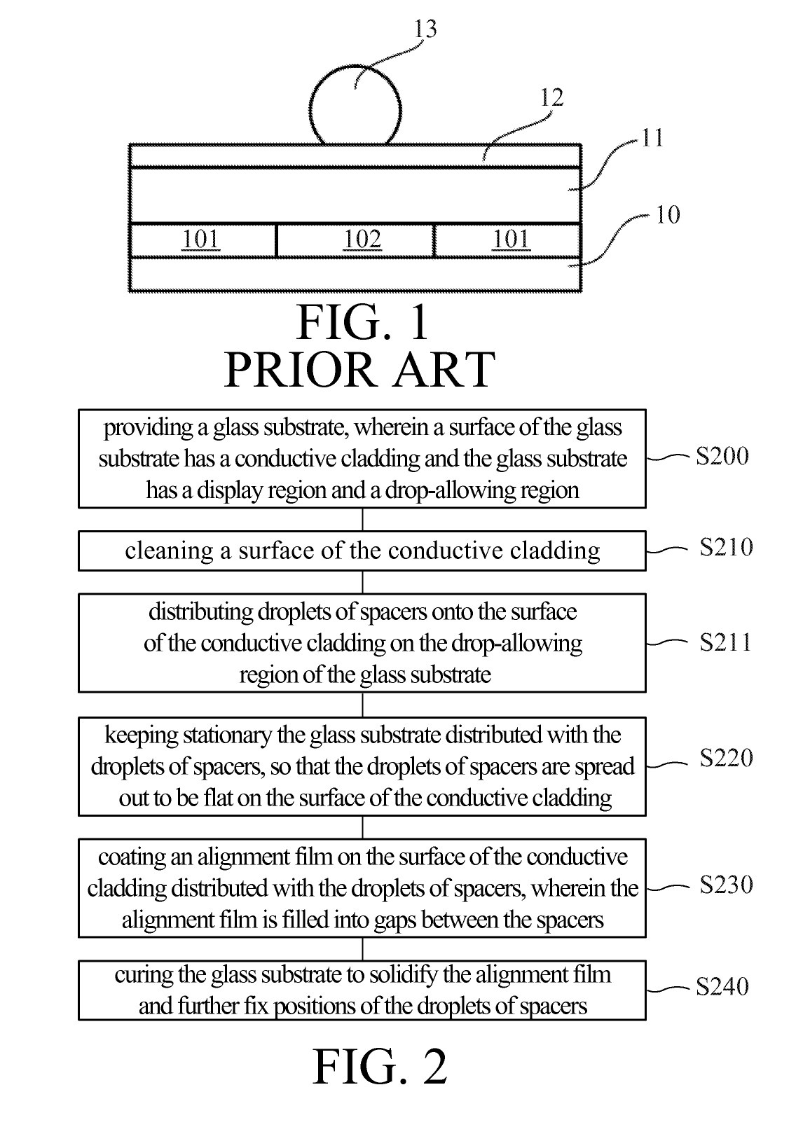

FIG. 2 is a flow chart of steps of a manufacturing method for a liquid crystal substrate according to a preferred embodiment of the present invention;

FIGS. 3A to 3D are schematic views of processes of the method as shown in FIG. 2 according to the preferred embodiment of the present invention.

### DETAILED DESCRIPTION OF THE PREFERRED EMBODIMENTS

A preferred embodiment of a coating method for spacers of a liquid crystal substrate and a manufacturing method for a liquid crystal substrate provided by the present invention can be described more detailed by referring to the accompanying drawings.

The structure and the technical means adopted by the present invention to achieve the above and other objects can be best understood by referring to the following detailed description of the preferred embodiments and the accompanying drawings. The specification of the present invention provides different embodiments to describe technical features of different implementations of the present invention, wherein arrangements of various components in the embodiments are used to clearly describe the content of the present invention, but the present invention is not limited thereto. Meanwhile, some repeated numerals in the different embodiments are used to simplify the description, but not mean the relationship between the different embodiments.

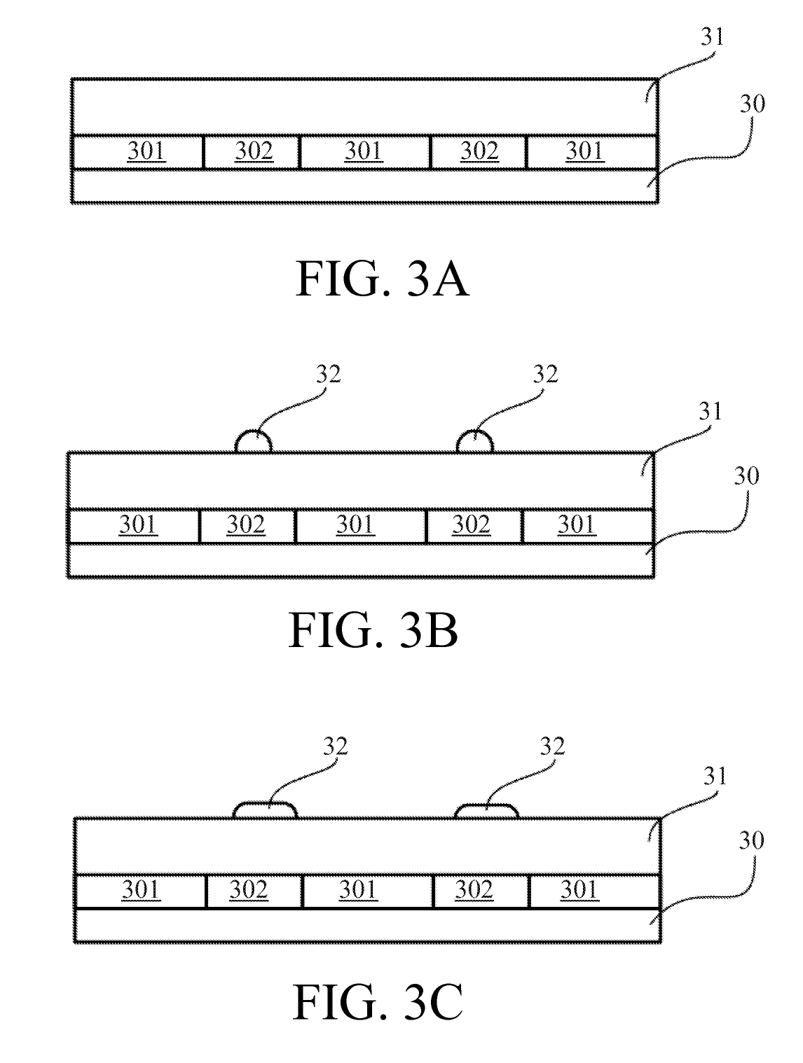

Referring now to FIG. 2, a flow chart of steps of a manufacturing method for a liquid crystal substrate according to a preferred embodiment of the present invention is illustrated, and comprises: a step (S200) of providing a glass substrate, wherein a surface of the glass substrate has a conductive cladding and the glass substrate has a display region and a drop-allowing region; a step (S210) of cleaning a surface of the conductive cladding; a step (S211) of distributing droplets of spacers onto the surface of the conductive cladding on the drop-allowing region of the glass substrate; a step (S220) of keeping stationary the glass substrate distributed with the droplets of spacers, so that the droplets of spacers are spread out to be flat on the surface of the conductive cladding; a step (S230) of coating an alignment film on the surface of the conductive cladding distributed with the droplets of spacers, wherein the alignment film is filled into gaps between the spacers; and a step (S240) of curing the glass substrate to solidify the alignment film and further fix positions of the droplets of spacers.

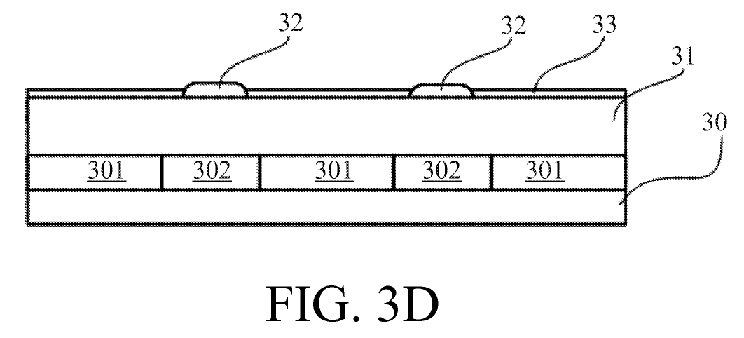

FIGS. 3A to 3D are schematic views of processes of the preferred embodiment of the present invention.

Referring to FIG. 3A and the step (S200) in FIG. 2, the step (S200) is to provide a glass substrate 30, wherein a surface of the glass substrate 30 has a conductive cladding 31 and the glass substrate 30 has a display region 301 and a drop-allowing region 302. In the embodiment, material of the conductive cladding 31 is indium tin oxide (ITO). The display region 301 are three types of color resists (i.e. red R, green G, and blue B) which are used to carry out a display function of LCD, while the drop-allowing regions 302 is black matrixes which have no display function and can be applied with spacers or other substances.

Referring to the step (S210) in FIG. 2, the step (S210) is to clean a surface of the conductive cladding 31. The physical and chemical properties of the conductive cladding 31 is relatively stable, and thus the conductive cladding 31 can be processed by conventional cleaning actions including cleaning processes of atmospheric pressure plasma and Excimer-UV.

Referring to FIG. 3B and the step (S211) in FIG. 2, the step (S211) is to distribute droplets of spacers 32 onto the surface of the conductive cladding 31 on the drop-allowing region 302 of the glass substrate 30. In the step, the droplets of spacers 32 are directly formed on the surface of the conductive cladding 31. The physical and chemical properties of the conductive cladding 31 are more stable than that of an alignment film. Thus, before executing the step (S211), the step (S210) is firstly executed to ensure that the surface of the conductive cladding 31 is clean. A clean surface is advantageous for the droplets of spacers 32 to be spread out from spherical droplets into a flat status. An ink-jet process is used to spray the droplets of spacers 32 onto the surface of the conductive cladding 31, so as to obtain the droplets of spacers 32 which are more evenly and finely distributed.

Referring to FIG. 3C and the step (S220) in FIG. 2, after the step (S211), it can selectively execute the step (S220) of keeping stationary the glass substrate 30 distributed with the droplets of spacers 32, so that the droplets of spacers 32 are spread out to be flat on the surface of the conductive cladding 31. Because the surface of the conductive cladding 31 is clean, the droplets of spacers 32 can be kept stationary a period of time and then spread out to be flat. The duration of this step needs to be ensured according to implementation conditions, and the duration may be affected by conditions including material and surface flatness of the conductive cladding 31, the viscosity of the droplets of spacers 32, and the temperature and humidity of an implementation environment. The flat droplets of spacers 32 are easy to keep on the drop-allowing region 302, and uneasy to slide on the surface of the conductive cladding 31 and deviate onto the display region 301. If the droplets of spacers 32 deviate onto the display region 301, the display effect of LCD may be affected, and LCD panels may become defective products.

The foregoing steps substantially describe a coating method for spacers of a liquid crystal substrate. The droplets of spacers 32 are directly applied on the surface of the conductive cladding 31, instead of applying the droplets of spacers 32 on the firstly coated the alignment film. The advantages of directly applying the droplets of spacers 32 on the surface of the conductive cladding 31 are that: it can ensure the cleanness of the coated surface, so as to be advantageous to spread out the droplets of spacers 32 and inhibit the sliding thereof. Furthermore, the physical and chemical properties of the conductive cladding 31 are stable. Thus, in a case that deviation of applying positions of the droplets of spacers 32 is found, it is easy to remove the droplets of spacers 32 and rework. Only if a suitable cleaning process is selected, it can ensure that the conductive cladding will not be scratched.

Specifically, when finishing executing the step (S220), further executing a detection step of detecting the distribution status of the droplets of spacers 32. When detecting that the surface of the conductive cladding 31 on the display region 301 is covered with the droplets of spacers 32, executing a step of clearing droplets of spacers 32 on the surface of the conductive cladding 31. After finishing clearing, re-executing the step (S210), the step (S211) and the step (S220). The droplets of spacers 32 can be cleared by a brush cleaning process.

Referring to FIG. 3D and the step (S230) in FIG. 2, the step (S230) is to coat an alignment film 33 on the surface of the conductive cladding 31 distributed with the droplets of spacers 32, wherein the alignment film 33 is filled into gaps between the droplets of spacers 32. The alignment film 33 also can be formed by a spraying process. The alignment film 33 is coated onto the surface of the conductive cladding 31 in a liquid status, and the droplets of spacers 32 are viscous droplets, so that the alignment film 33 can be easily filled into gaps between the droplets of spacers 32.

Referring to the step (S240) in FIG. 2, after the step (S230), it can selectively execute the step (S240) of curing the glass substrate 30 to solidify the alignment film 33 and further fix positions of the droplets of spacers 32. The curing can be executed in a specific curing oven, wherein the temperature thereof should be suitably controlled to solidify the alignment film 33 without decomposing the chemical compositions of the alignment film 33 and the droplets of spacers 32. A suitable temperature is determined after experiments according to the compositions of the alignment film 33 and the droplets of spacers 32. After curing, the droplets of spacers 32 are further fixed on the drop-allowing region 302 of the glass substrate 30 to prevent from shifting.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A manufacturing method for a liquid crystal substrate, comprising:
providing a glass substrate, wherein a surface of the glass substrate has a conductive cladding and the glass substrate has a display region and a drop-allowing region;
cleaning a surface of the conductive cladding;
distributing droplets of spacers onto the surface of the conductive cladding on the drop-allowing region of the glass substrate;
keeping stationary the glass substrate distributed with the droplets of spacers, so that the droplets of spacers are spread out to be flat on the surface of the conductive cladding;
detecting if the surface of the conductive cladding on the display region is distributed with the droplets of spacers; and if there are the droplets of spacers, clearing the droplets of spacers on the surface of the conductive cladding;
coating an alignment film on the surface of the conductive cladding distributed with the droplets of spacers, wherein the alignment film is filled into gaps between the spacers; and
curing the glass substrate to solidify the alignment film and further fix positions of the droplets of spacers.

2. The manufacturing method for the liquid crystal substrate according claim 1, wherein the step of clearing the droplets of spacers on the surface of the conductive cladding comprises:
using a brush cleaning process to clear the droplets of spacers on the surface of the conductive cladding.

3. The manufacturing method for the liquid crystal substrate according claim 1, wherein the step of distributing the droplets of spacers onto the surface of the conductive cladding comprises:
using an ink-jet process to spray the droplets of spacers onto the surface of the conductive cladding.

4. A coating method for spacers of a liquid crystal substrate, comprising:
providing a glass substrate, wherein a surface of the glass substrate has a conductive cladding and the glass substrate has a display region and a drop-allowing region;
cleaning a surface of the conductive cladding; and
distributing droplets of spacers onto the surface of the conductive cladding on the drop-allowing region of the glass substrate.

5. The coating method for spacers of the liquid crystal substrate according to claim 4, wherein after distributing the droplets of spacers onto the surface of the conductive cladding on the drop-allowing region of the glass substrate, further comprising the following step of:
keeping stationary the glass substrate distributed with the droplets of spacers, so that the droplets of spacers are spread out to be flat on the surface of the conductive cladding.

6. The coating method for spacers of the liquid crystal substrate according to claim 5, wherein after the droplets of spacers are spread out to be flat, further comprising the following step of:
detecting if the surface of the conductive cladding on the display region is distributed with the droplets of spacers; and
if there are the droplets of spacers, clearing the droplets of spacers on the surface of the conductive cladding.

7. The coating method for spacers of the liquid crystal substrate according to claim 6, wherein after clearing the droplets of spacers on the surface of the conductive cladding, further comprising the following step of:
re-executing the steps of cleaning the surface of the conductive cladding and distributing the droplets of spacers.

8. The coating method for spacers of the liquid crystal substrate according to claim 6, wherein the step of clearing the droplets of spacers on the surface of the conductive cladding comprises:
using a brush cleaning process to clear the droplets of spacers on the surface of the conductive cladding.

9. The coating method for spacers of the liquid crystal substrate according to claim 4, wherein the step of distributing the droplets of spacers onto the surface of the conductive cladding comprises:
using an ink-jet process to spray the droplets of spacers onto the surface of the conductive cladding.

10. A manufacturing method for a liquid crystal substrate, comprising:
providing a glass substrate, wherein a surface of the glass substrate has a conductive cladding and the glass substrate has a display region and a drop-allowing region;
cleaning a surface of the conductive cladding;
distributing droplets of spacers onto the surface of the conductive cladding on the drop-allowing region of the glass substrate; and
coating an alignment film on the surface of the conductive cladding distributed with the droplets of spacers, wherein the alignment film is filled into gaps between the spacers.

11. The manufacturing method for the liquid crystal substrate according to claim 10, wherein after distributing the droplets of spacers onto the surface of the conductive cladding on the drop-allowing region of the glass substrate and before coating the alignment film on the surface of the conductive cladding distributed with the droplets of spacers, further comprising the following step of:
keeping stationary the glass substrate distributed with the droplets of spacers, so that the droplets of spacers are spread out to be flat on the surface of the conductive cladding.

12. The manufacturing method for the liquid crystal substrate according to claim 10, wherein after the step of coating the alignment film, further comprising the following step of:
curing the glass substrate to solidify the alignment film and further fix positions of the droplets of spacers.

13. The manufacturing method for the liquid crystal substrate according to claim 11, wherein after the droplets of spacers are spread out to be flat, further comprising the following step of:
detecting if the surface of the conductive cladding on the display region is distributed with the droplets of spacers; and
if there are the droplets of spacers, clearing the droplets of spacers on the surface of the conductive cladding.

14. The manufacturing method for the liquid crystal substrate according to claim 13, wherein after clearing the droplets of spacers on the surface of the conductive cladding, further comprising the following step of:
re-executing the steps of cleaning the surface of the conductive cladding and distributing the droplets of spacers.

15. The manufacturing method for the liquid crystal substrate according to claim 13, wherein the step of clearing the droplets of spacers on the surface of the conductive cladding comprises:
using a brush cleaning process to clear the droplets of spacers on the surface of the conductive cladding.

16. The manufacturing method for the liquid crystal substrate according to claim 10, wherein the step of distributing the droplets of spacers onto the surface of the conductive cladding comprises:
using an ink-jet process to spray the droplets of spacers onto the surface of the conductive cladding.
